(19) United States
(12) Patent Application Publication
(10) Pub. No.: US 2002/0024122 A1
(43) Pub. Date: Feb. 28, 2002

(54) Lead frame having a side ring pad and semiconductor chip package including the same

(75) Inventors: Young-Doo Jung, Kyungki-do (KR); Kwon-Young Roh, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-City Kyungki-do (KR)

(21) Appl. No.: 09/909,736

(22) Filed: Jul. 19, 2001

(30) Foreign Application Priority Data
Aug. 25, 2000 (KR) 2000-49460

(51) Int. Cl. H01L 23/495

(52) U.S. Cl. 257/666

(57) ABSTRACT

A lead frame and a semiconductor chip package including a side ring pad are disclosed. In the present invention, According to the present invention, a lead frame is provided with a die pad on which a semiconductor chip is mounted. A plurality of inner leads is electrically interconnected to corresponding electrode pads by a plurality of bonding wires. A side ring pad is disposed around the die pad and between the die pad and the inner leads. A tie bar connects the die pad and the side ring pad. The electrode pads include power electrode pads that are electrically interconnected to the side ring pad by power bonding wires. The bonding wires may include first link bonding wires connected between the electrode pads and the metal pads and second link boding wires connected between the metal pads and the inner leads.

With the present invention, grounding capacity and high frequency characteristics of a semiconductor chip package are improved and ground noise is reduced. Further, the inner leads can be placed more freely and flexibility of the bonding wires is enhanced. Moreover, it is possible to meet the fine lead and high-pin-count requirements that are required of modem packages at lower cost.

### BACKGROUND OF THE INVENTION

1. Technical Field of the Invention

This invention relates to a semiconductor packaging technology, and more particularly to a lead frame having a side ring pad disposed between inner leads and a die pad, and semiconductor chip packages implementing such a lead frame.

2. Description of Related Art

It becomes more and more difficult to manufacture plastic packages devices having high input/output (I/O) pin counts, as integrated circuit chips to be packaged are developed to have enhanced performance and higher operational frequency. When the operational frequency is higher in a semiconductor chip package using a metal lead frame, the inductive factor increases in signal paths or power supply paths, which results in an increase of signal noise. In order to prevent the signal noise, more I/O pins are advantageous. However, the increase in number of the I/O pins has a drawback, because it inevitably entails an increase in the package size. To reduce the overall package size while maintaining high I/O pin count, the pitch of the leads must be small. However, the fine lead pitch makes the leads fragile and susceptible to breakage during the assembly process and use in package form. In addition, to make larger numbered I/O pins, the pins must be disposed farther from the die pad, which results in longer bonding wires (greater wire span). It is difficult to maintain proper wire loop of the longer wires and failures such as wire sweepings may occur because of the high pressure of a mold resin encapsulant. Therefore, very high reliability in the wire bonding process is required and the increase of the inductance of the bonding wire is inevitable.

For overcoming such problems, some approaches use solder balls in place of the leads or employ CSP (Chip Size Package or Chip Scale Package) structures. However, these approaches require specific machinery and increase the unit cost of the production.

In the meantime, devices used in the telecommunication industry such as applied to CDMA (Code Divisional Multiple Access) require high ground capacity since they have high frequency characteristics. For the high frequency features, a die pad of the lead frame is exposed at the bottom surface of the package body and the exposed side of the die pad is used for ground terminal of the package. However, the surface of the die pad in the conventional exposed structure is weak in bonding strength with the wires and thus the ground bonding wires bonded to the die pad becomes weakened at the stitch area. A reliability verification test carried out by the inventors showed that about 80 percent of the wires were detached from the die pad surface when using the MRFIC 1854 device with 20TSSOP exposed die pad available from Motorola. The purpose of the reliability verification test was to detect in advance potential problems that may occur when a package device is mounted onto a printed circuit board.

To keep up with the trend of the fine lead pitch, the QFP (Quad Flat Package) structure can be adopted by placing leads around four sides of the die pad. However, the QFP structure is difficult to apply to a package having a great numbers of ground pins and power supply pins, because in a QFP package the wire span is limited by a 100D rule (maximum wire span is limited to up to one hundred times the diameter (D) of a bonding wire, where the wire span means a distance from an electrode pad to a corresponding inner lead, which are electrically interconnected by a bonding wire), the number of pins is limited and the flexibility of inner lead disposition and the wire bonding becomes poor.

### SUMMARY OF THE INVENTION

The present invention provides a novel structure for a lead frame and a semiconductor chip package using the lead frame, which can improve high frequency characteristics of semiconductor chip packages. Further, the present invention makes it possible to produce at lower cost a semiconductor chip package having high I/O counts and fine pitch leads. Moreover, according to the present invention, the inner leads are disposed more freely and the reliability of bonding wires is enhanced.

According to the present invention, a lead frame is provided with a die pad on which a semiconductor chip is mounted. A plurality of inner leads are electrically interconnected to corresponding electrode pads by a plurality of bonding wires. A side ring pad is disposed around the die pad and between the die pad and the inner leads. A tie bar connects the die pad and the side ring pad. The electrode pads include power electrode pads that are electrically interconnected to the side ring pad by power bonding wires. The bonding wires may include first link bonding wires connected between the electrode pads and the metal pads and second link boding wires connected between the metal pads and the inner leads.

These and other features, and advantages thereof, will be more clearly understood from the following detailed description taken in conjunction with the accompanying drawings. It is important to point out that the illustrations may not necessarily be drawn to scale, and that there may be other embodiment of this invention which are not specifically illustrated.

### BRIEF DESCRIPTION OF THE INVENTION

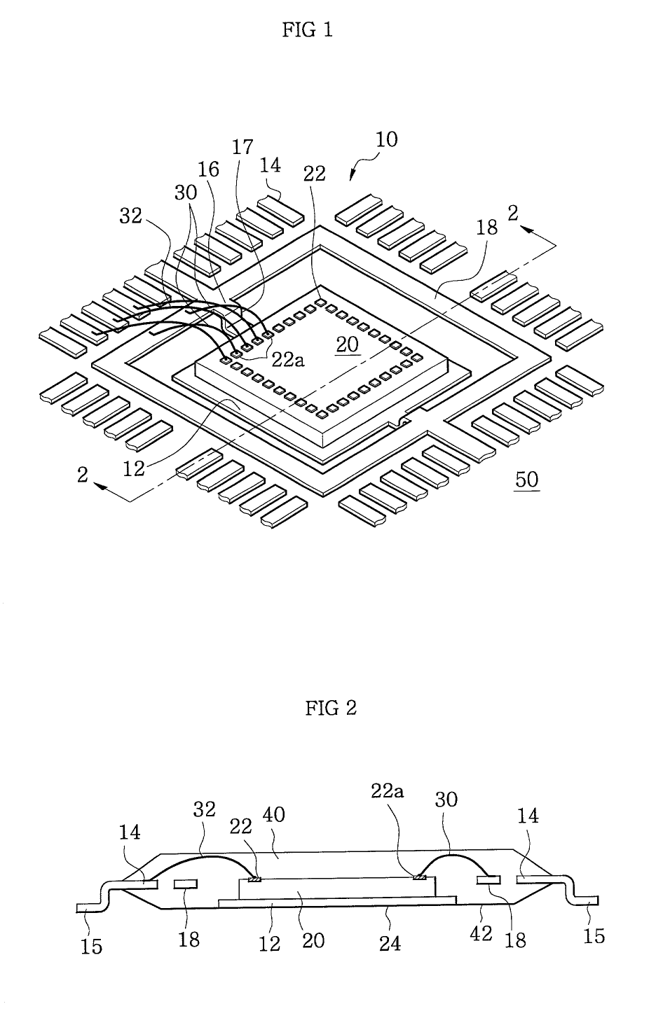

FIG. 1 is a partial perspective view of a semiconductor chip package according to an embodiment of the present invention.

FIG. 2 is a cross-sectional view of the semiconductor chip package taken along the line 2-2 in FIG. 1.

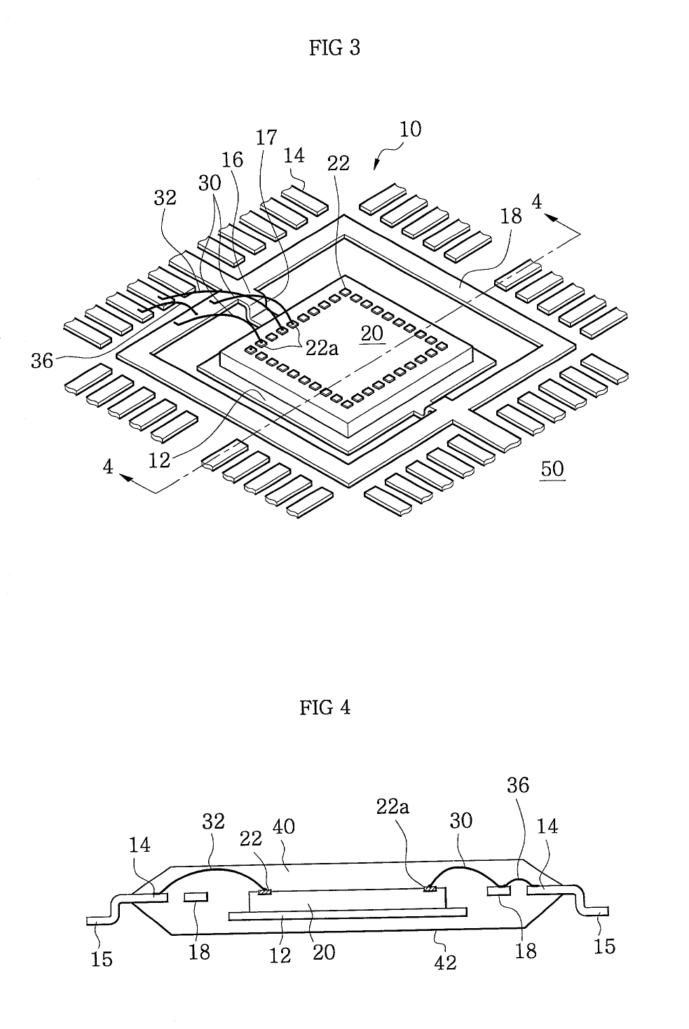

FIG. 3 is a partial perspective view of a semiconductor chip package according to another embodiment of the present invention.

FIG. 4 is a cross-sectional view of the semiconductor chip package taken along the line 4-4 in FIG. 3.

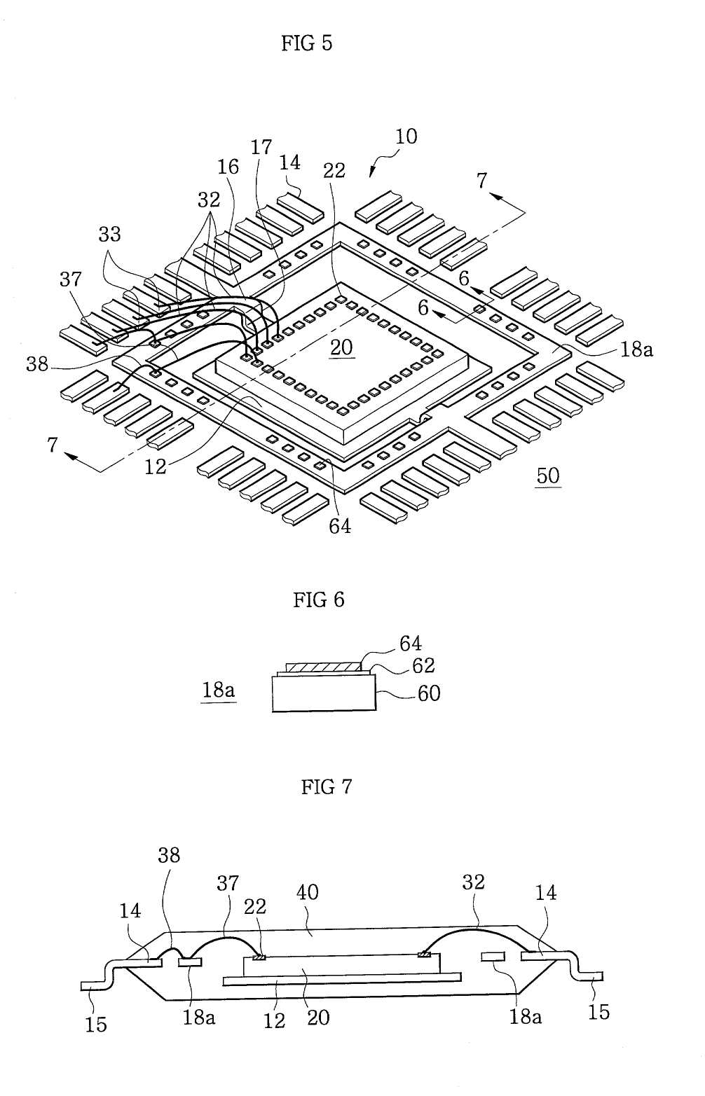

FIG. 5 is a partial perspective view of a semiconductor chip package according to still another embodiment of the present invention.

FIG. 6 is a cross-sectional view of a side ring suitable for use in the present invention.

FIG. 7 is a cross-sectional view of the semiconductor chip package taken along the line 7-7 of the present invention.

### DETAILED DESCRIPTION OF PREFERRED EMBODIMENTS

FIG. 1 is a partial perspective view of a semiconductor chip package of the present invention, and FIG. 2 is a cross-sectional view of the package taken along the line 2-2 of FIG. 1.

Referring to FIGS. 1 and 2, a lead frame 10 comprises a die pad 12, inner leads 14, outer leads 15, tie bars 16, bent portions 17, and a side ring pad 18. The lead frame 10 can be made of a copper, a copper alloy, a nickel-iron alloy or a nickel-iron-cobalt alloy. It should be apparent to a person skilled in the art that other suitable conductive material can be used for the lead frame 10. In the process, the lead frame includes a number of unit frames shown in FIG. 1, and each frame is interconnected by a side rail (not shown for simplicity).

To a chip attachment surface (upper surface in the drawing) of the die pad 12 is attached a semiconductor chip 20 by a die bonding process. In the periphery of an active surface of the semiconductor chip 20, a plurality of bond pads 22 are formed. The bond pads 22 can be made of aluminum metal and act as electrical paths between internal circuit elements of the chip and outer devices (not shown). The bond pads 22 of the chip 20 are electrically interconnected to the inner leads 14 by bonding wires 32 including ground bonding wires 30. The connection of the bonding wires 32 are performed using a typical wire bonding process. For Example, the wires 32 are ball-bonded to the bond pads 22 and then moved toward and stitch-bonded to bonding areas of the inner leads 14. In order to simplify the drawing, only some wires are shown.

In this embodiment, the side ring pad 180 functions as a ground pad for the semiconductor chip 20. That is, among a plurality of the bond pads 22 of the chip 20, ground electrode pads 22a are electrically interconnected to the side ring pad 18 by the ground bonding wires 30. Chip current can flow through both the side ring pad 18 and the die pad 12 connected to the side ring pad 18 by the tie bar 16. This means that the grounding capacity or capability of the semiconductor chip increases.

Further, in this embodiment, the die pad 12 has a bottom surface 24 lying at the same plane with a bottom side 42 of the package 50, so that the bottom surface of the die pad 12 is exposed from the mold resin 40. Therefore, the high grounding capacity required in high frequency devices is met.

Moreover, since the ground bonding wires 30 are not bonded to the die pad 12 but to the side ring pad 18, the detachment of the ground bonding wires 30 can be prevented while using an exposed die pad structure.

The tie bar 16 supports the die pad 12 to be mechanically connected to a side rail of the lead frame 10 as well as interconnects the die pad 12 to the side ring pad 18 both electrically and mechanically. The tie bar 16 includes the bent portions 17 for maintaining the co-planarity of the inner leads 14 and the semiconductor chip 20. The dimension of the bent portions 17 depends on the types of the package to be used.

With regard to the embodiment shown in FIGS. 1 and 2, the power delivery path includes the die pad 12 and the side ring pad 18. Therefore, the inductance of the power delivery path is lowered and power noise is prevented so that high frequency devices operate stably.

FIG. 3 is a partial perspective view of a semiconductor chip package according to another embodiment of the present invention, and FIG. 4 is a cross-sectional view of the semiconductor chip package taken along line 4-4 in FIG. 3.

As explained above, the QFP package is suitable for use in devices requiring high pin counts. The more leads in the QFP package may limit the flexibility in the placing of the leads. Thus, if a number of power electrode pads are formed on the chip, it is difficult to use single common inner leads for the power electrode pads with the conventional QFP package. In contrast, the present invention can use the side ring pad 18 as a single common power lead, and thus able to overcome the limitation of the lead placement. As shown in FIGS. 2-4, the power bonding wires 30 interconnect the side ring pad 18 and the power electrode pads 22a of the semiconductor chip 20, and then the power inner leads 14 are interconnected to the side ring pad 18 by the bonding wire 36, so that the power inner leads 14 can be placed in any position independent of the location of the power electrode pads 22a. In addition, the inventive structure reduces the number of power leads.

For example, a prior art QFP package having one hundred (100) pins uses twenty-four (24) ground leads, while the present invention QFP structure can use only one (1) ground lead by using the side ring pad 8 as a common ground lead. Therefore, the present invention QFP structure provide more space for signal leads, so that the inner leads can be disposed more freely by a designer and the bonding reliability of wires is improved. Further, the wire span can be reduced and the inner leads can be closer to the die pad 12, which results in the reduction of the overall package size.

FIG. 5 is a partial perspective view of a semiconductor chip package according to still another embodiment of the present invention, FIG. 6 is a cross-sectional view of a side ring suitable for use in the present invention, and FIG. 7 is a cross-sectional view of the semiconductor chip package taken along line 7-7 of the present invention.

In this example, a side ring pad 18a includes an insulating layer 60 and a plurality of metal pads 64 attached onto the layer 60 by an adhesive 62. The insulating layer 60 is, for example, a polyimide tape, and the metal pads 64 are formed by attaching copper metal patterns on the polyimide tape. The adhesive 62 is, for example, an epoxy adhesive either in the form of a liquid or a tape.

The bond pads 22 of the semiconductor 20 may be directly interconnected to the inner leads 14 via the bonding wires 32. The bond pads 22 may also be interconnected to the inner leads 14 by connecting the side ring pads 18a and the metal pads 64 with the first link bonding wire 37 and the second link bonding wire 38. As a result, even when an electrode pad is to be connected to the farthest inner lead (e.g., inner leads in corner), the electrical connection can be made without using longer bonding wires.

In the drawings and specification, there have been disclosed typical preferred embodiments of this invention and, although specific terms are employed, they are used in a generic and descriptive sense only and not for purposes of limitation, the scope of this invention being set forth in the following claims.

What is claimed is:

1. A lead frame comprising:
a die pad on which a semiconductor chip having an active surface where a plurality of electrode pads are formed is mounted;
a plurality of inner leads electrically interconnected to corresponding electrode pads by a plurality of bonding wires;
a side ring pad disposed around the die pad and between the die pad and the inner leads; and
a tie bar arranged to connect the die pad and the side ring pad,
wherein said plurality of electrode pads includes power electrode pads which are electrically interconnected to the side ring pad by power bonding wires.

2. The lead frame as claimed in claim 1, wherein the die pad, the inner leads, and the tie bar are made of the same metal.

3. The lead frame as claimed in claim 1, further comprising a plurality of outer leads made in one body with the plurality of inner leads.

4. The lead frame as claimed in claim 1, wherein the tie bar include a bent portion arranges to maintain the co-planarity of the semiconductor chip and the inner leads.

5. The lead frame as claimed in claim 4, wherein the die pad, the inner leads, and the tie bar are made of the same metal.

6. The lead frame as claimed in claim 4, further comprising a plurality of outer leads made in one body with the plurality of inner leads.

7. A lead frame comprising:
a die pad on which a semiconductor chip having an active surface where a plurality of electrode pads are formed is mounted;
a plurality of inner leads electrically interconnected to corresponding electrode pads by a plurality of bonding wires;
a side ring pad disposed around the die pad and between the die pad and the inner leads; and
a tie bar arranged to connect the die pad and the side ring pad,
wherein said side ring pad includes a plurality of conductive pads formed thereon.

8. The lead frame as claimed in claim 7, wherein the plurality of bonding wires include first link bonding wires connected between the electrode pads and the conductive pads and second link boding wires connected between the conductive pads and the inner leads.

9. The lead frame as claimed in claim 8, wherein inner leads to which both the first and the second link bonding wires are bonded are disposed at corners of the lead frame.

10. A semiconductor chip package comprising:
a semiconductor chip having an active surface where a plurality of electrode pads are formed;
a lead frame having a plurality of leads;
a plurality of bonding wires electrically interconnecting the electrode pads and corresponding leads;
an encapsulant covering the semiconductor chip, thereby forming a package body;
said lead frame comprising:
a die pad on which the semiconductor chip is mounted;
a plurality of inner leads electrically interconnected to corresponding electrode pads by a plurality of bonding wires;
a side ring pad disposed around the die pad and between the die pad and the inner leads; and
a tie bar arranged to connect the die pad and the side ring pad,
wherein said plurality of electrode pads includes power electrode pads which are electrically interconnected to the side ring pad by power bonding wires.

11. The semiconductor chip package as claimed in claim 10, wherein the die pad has a bottom surface exposed from the package body.

12. A semiconductor chip package comprising:
a semiconductor chip having an active surface where a plurality of electrode pads are formed;
a lead frame having a plurality of leads;
a plurality of bonding wires electrically interconnecting the electrode pads and corresponding leads;
an encapsulant encapsulating the semiconductor chip, thereby forming a package body;
said lead frame comprising:
a die pad on which the semiconductor chip is mounted;
a plurality of inner leads electrically interconnected to corresponding electrode pads by a plurality of bonding wires;
a side ring pad disposed around the die pad and between the die pad and the inner leads;
a tie bar for connecting the die pad and the side ring pad; and
said side ring pad includes a plurality of metal pads formed thereon.

13. The semiconductor chip package as claimed in claim 12, wherein the plurality of bonding wires include first link bonding wires connected between the electrode pads and the metal pads and second link boding wires connected between the metal pads and the inner leads.

14. A lead frame comprising:
a die pad on which a semiconductor chip having a plurality of bond pads is mounted;
a side ring pad disposed around the die pad;
a power inner lead electrically connected to the side ring pad, the side ring pad being disposed between the die pad and the power inner lead; and
a tie bar arranged to connect the die pad and the side ring pad;
wherein said plurality of electrode pads include power electrode pads which are electrically interconnected to the side ring pad.

15. The lead frame of claim 14, wherein the power electrode pads are electrically interconnected to the side ring pad by power bonding wires.
